(19) United States
(12) Patent Application Publication
(10) Pub. No.: US 2026/0268948 A1
(43) Pub. Date: Sep. 10, 2026

(54) SEMICONDUCTOR DEVICE

(71) Applicant: Renesas Electronics Corporation, Tokyo (JP)

(72) Inventors: Takeshi YAMAMOTO, Tokyo (JP); Yukio ICHIHARA, Tokyo (JP)

(21) Appl. No.: 19/558,879

(22) Filed: Mar. 6, 2026

(30) Foreign Application Priority Data
Mar. 7, 2025 (JP) 2025-036462

(51) Int. Cl. G11C 5/14

(52) U.S. Cl. CPC G11C 5/148

(57) ABSTRACT

A semiconductor device includes a first power supply line configured to transmit a power supply voltage, a second power supply line to which the power supply voltage is supplied via a P type transistor controlled by a processor power control signal from a power supply manager, and an R-FF circuit including a latch circuit and a flip-flop circuit and capable of saving data stored in the flip-flop circuit to the latch circuit by a retention control signal from the power supply manager and retaining the saved data. Here, the flip-flop circuit operates using the voltage on the second power supply line as a power supply voltage, the latch circuit is connected to a signal line configured to transmit the retention control signal by diodes, and the latch circuit operates using a voltage supplied via the diodes as a power supply voltage when it retains the data.

### CROSS-REFERENCE TO RELATED APPLICATIONS

The disclosure of Japanese Patent Application No. 2025-036462 filed on Mar. 7, 2025 including the specification, drawings and abstract is incorporated herein by reference in its entirety.

### BACKGROUND

The present invention relates to a semiconductor device, and more particularly to a semiconductor device including a memory circuit capable of promptly restoring data while reducing standby current, for example, during power cut-off.

There is disclosed a technique listed below.

Patent Document 1 Japanese Unexamined Patent Application Publication No. 2008-527822

As a memory circuit capable of promptly restoring data while reducing standby current during power cut-off, there is, for example, a memory circuit including a balloon latch circuit. For example, Patent Document 1 discloses a memory circuit including a balloon latch circuit.

For example, FIG. 1 of Patent Document 1 illustrates a latch circuit (2) including, as a memory circuit, a balloon latch (balloon latch circuit) made up of inverters (12, 14), and a master latch and a slave latch (4, 6).

### SUMMARY

Before power is cut off, for example, data held in a master latch or a slave latch (4, 6) is saved in a balloon latch (12, 14). Thereafter, the power supply to the master latch and the slave latch is cut off. At this time, power is supplied to the balloon latch, and the data saved in advance is retained. In the subsequent power restoration, the data retained in the balloon latch is returned to the master latch or the slave latch, thereby restoring the state. As a result, it is possible to reduce the standby current of the memory circuit during power cut-off and to promptly return (restore) the data to the memory circuit at the time of power restoration.

However, as a result of studies conducted by the inventors of this application, it has been found that such a memory circuit capable of retaining data even during power cut-off (hereinafter referred to also as a retention memory circuit or an R-FF (flip-flop) circuit) has the following problems.

In layout design of a semiconductor device, circuits such as R-FF circuits are treated as one cell, and design is carried out on a cell-by-cell basis. The R-FF circuit includes, on a cell basis, a power supply terminal subject to power cut-off and a power supply terminal not subject to power cut-off. Here, the power supply terminal subject to power cut-off is a terminal that supplies a power supply voltage to the master latch and the slave latch, and is connected to a power supply line whose power supply is cut off during cut-off (standby period). On the other hand, the power supply terminal not subject to power cut-off is a terminal that supplies a power supply voltage to the balloon latch, and is connected to a power supply line whose power supply is not cut off during cut-off. In order to supply power to each of R-FF circuits, metal lines for these two types of power supply lines are arranged in a mesh pattern on a semiconductor chip constituting the semiconductor device, and are connected to the power supply terminals of the respective R-FF circuits.

Metal lines on the semiconductor chip are used not only as power supply lines but also as signal lines for transmitting signals. Therefore, as the resources of metal lines used as power supply lines increase, the resources of metal lines that can be used as signal lines decrease. For example, when the resources of metal lines that can be used as signal lines are insufficient, a larger semiconductor chip is used to secure the resources for signal lines.

Since the R-FF circuit requires more power supply lines as described above than a memory circuit that does not have a function of retaining data during power cut-off (standby period), there arises a problem that the size of the semiconductor chip increases and manufacturing cost increases.

An overview of a representative embodiment of embodiments disclosed in this application will be briefly described as follows.

That is, a semiconductor device according to one embodiment includes a first power supply line configured to transmit a first power supply voltage, a second power supply line to which the first power supply voltage is supplied via a switch circuit controlled by a first control signal from a power supply manager and a memory circuit having a latch circuit and a flip-flop circuit and capable of saving data stored in the flip-flop circuit to the latch circuit by a second control signal from the power supply manager and retaining the saved data. Here, the flip-flop circuit operates using the first power supply voltage on the second power supply line as a power supply voltage, the latch circuit is connected to a signal line configured to transmit the second control signal by a first unidirectional circuit, and the latch circuit operates using a second power supply voltage supplied via the first unidirectional circuit as a power supply voltage when it retains the data.

Other problems and novel features will become apparent from the description of this specification and the accompanying drawings.

According to one embodiment, it is possible to provide a semiconductor device capable of reducing the manufacturing cost.

### BRIEF DESCRIPTION OF THE DRAWINGS

FIG. 1 is a block diagram illustrating a specific example of a semiconductor device according to the first embodiment.

FIG. 2 is a diagram for describing an R-FF circuit according to the first embodiment.

FIG. 3 is a circuit diagram illustrating a configuration of the R-FF circuit according to the first embodiment.

FIG. 4 is a diagram for describing the semiconductor device according to the first embodiment.

FIG. 5 is a block diagram illustrating a configuration of a unit repeater circuit according to the first embodiment.

FIG. 6 is a diagram illustrating a relationship between the unit repeater circuit and the R-FF circuit according to the first embodiment.

FIG. 7 is a truth table for describing an operation of a latch circuit according to the first embodiment.

FIG. 8 is a schematic cross-sectional view for describing the first modification according to the first embodiment.

FIG. 9 is a circuit diagram illustrating a configuration of an R-FF circuit according to the second embodiment.

FIG. 10 is a block diagram illustrating an overview of the semiconductor device according to the first embodiment.

FIG. 11 is a timing chart illustrating an operation of the semiconductor device according to the first embodiment.

### DETAILED DESCRIPTION

Hereinafter, embodiments of the present invention will be described with reference to the drawings. Note that the disclosure is merely an example, and appropriate modifications that can be easily conceived by those skilled in the art while maintaining the gist of the invention are naturally included in the scope of the present invention.

In addition, in this specification and all the drawings, the same reference signs are assigned to the same elements as those described in the previous drawings, and the detailed description thereof may be omitted as appropriate.

### First Embodiment

### Overview of Semiconductor Device and Operation

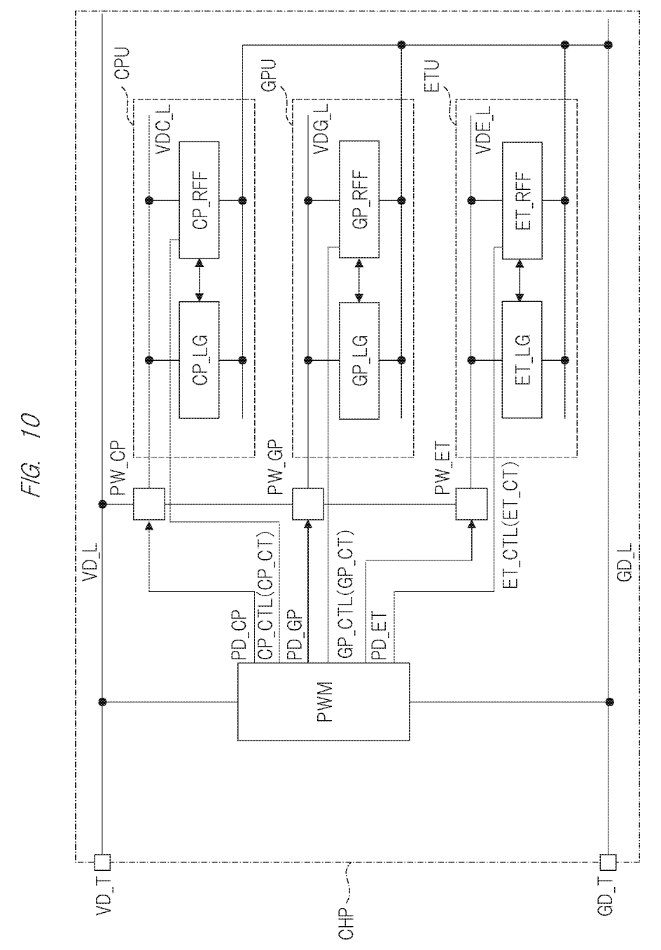

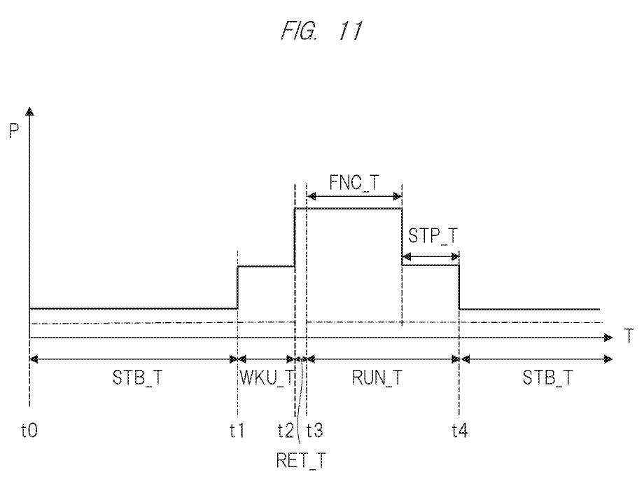

FIG. 10 is a block diagram illustrating an overview of a semiconductor device according to the first embodiment, and FIG. 11 is a timing chart illustrating an operation of the semiconductor device according to the first embodiment.

In FIG. 10, CHP surrounded by a dot-dashed line denotes a semiconductor device. The semiconductor device CHP includes a semiconductor chip, a package encapsulating the semiconductor chip, and external terminals protruding from the package.

The semiconductor device CHP includes a large number of external terminals, but a power supply external terminal VD_T and a ground external terminal GD_T are only depicted on the dot-dashed line in FIG. 10. Though not particularly limited, the semiconductor chip CHP operates using, as power supply voltages, a power supply voltage VDD (not illustrated) supplied to the power supply external terminal VD_T and a ground voltage GND (not illustrated) supplied to the ground external terminal GD_T.

Although a plurality of circuit blocks, power supply lines (including ground line), and signal lines are formed on the semiconductor chip, the circuit blocks, the power supply lines, and the signal lines necessary for the description are only depicted in FIG. 10. FIG. 10 illustrates, as circuit blocks, only a processor CPU configured to execute processing according to a program (not illustrated), a graphics unit GPU configured to execute display processing, an other unit ETU including peripheral circuits and the like, a power supply manager PWM, and power switch circuits PW_CP, PW_GP, and PW_ET. Further, in FIG. 10, VD_L denotes a power supply line (first power supply line) connected to the power supply external terminal VD_T, and GD_L denotes a ground line connected to the ground external terminal GD_T. The power supply line VD_L supplies the power supply voltage VDD to the power supply manager PWM and the power switch circuits PW_CP, PW_GP, and PW_ET. In addition, the ground line GD_L supplies the ground voltage GND to the power supply manager PWM, the processor CPU, the graphics unit GPU, and the other unit ETU.

Note that the processor CPU, the graphics unit GPU, and the other unit ETU are connected by a plurality of signal lines (not illustrated), and data are transmitted and received therebetween via the signal lines so as to implement the function of the semiconductor device CHP.

### Power Supply Manager PWM

The power supply manager PWM operates using, as power supply voltages, the power supply voltage VDD supplied via the power supply line VD_L and the ground voltage GND supplied via the ground line GD_L. As will be described later with reference to FIG. 11, the power supply manager PWM reduces the current consumption of the semiconductor device CHP by cutting off the power supply voltage VDD supplied to the processor CPU, the graphics unit GPU, and the other unit ETU.

### Processor CPU

The processor CPU include a logic circuit CP_LG operating according to a program and a memory device CP_RFF. The memory device CP-RFF is connected to the logic circuit CP_LG, and for example, temporarily retains data generated by the logic circuit CP_LG and supplies the data to the logic circuit CP_LG again. The logic circuit CP_LG and the memory device CP_RFF are connected to a power supply line (second power supply line) VDC_L and the ground line GD_L.

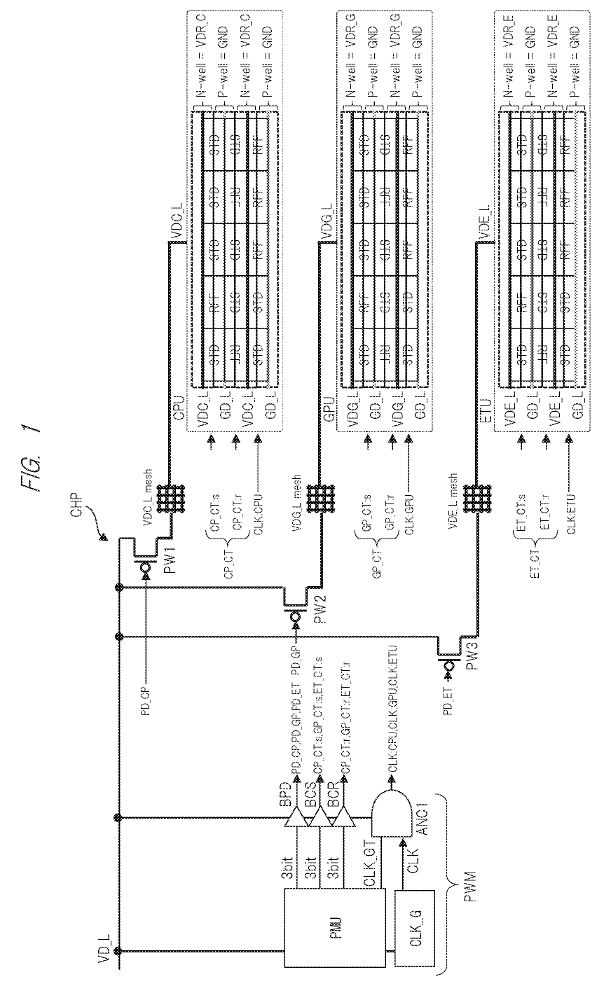

In this figure, in order to make the description easier, each of the logic circuit CP_LG and the memory device CP_RFF is illustrated as one circuit block, but as will be illustrated later in FIG. 1 and the like, the circuits constituting the logic circuit CP_LG and the circuits constituting the memory device CP_RFF are arranged in a mixed manner when the semiconductor chip is viewed in plan view.

The power supply line VDC_L is made up of a plurality of power supply lines arranged in a mesh pattern on the semiconductor chip when viewed in plan view, and is connected to the power supply line VD_L via the power switch circuit PW_CP. The power switch circuit PW_CP is controlled to be switched on and off by a processor power control signal (first control signal) PD_CP output from the power supply manager PWM. When the power switch circuit PW_CP is set to a conductive state by the first control signal PD_CP, the logic circuit CP_LG and the memory device CP_RFF operate using, as power supply voltages, the power supply voltage (first power supply voltage) VDD supplied from the power supply line VD_L to the power supply line VDC_L via the power switch circuit PW_CP and the ground voltage GND supplied via the ground line GD_L.

The memory device CP_RFF includes a plurality of R-FF circuits RFF (not illustrated). The memory device CP_RFF is connected to the power supply manager PWM via a signal line CP_CTL. The power supply manager PWM supplies a retention control signal (second control signal) CP_CT to the memory device CP_RFF by the signal line CP_CTL. In the R-FF circuit RFF in the memory device CP_RFF, data transfer between a master latch or a slave latch and a balloon latch circuit is controlled by the second control signal CP_CT. As will be described in detail later, in the semiconductor device CHP according to the first embodiment, a voltage on the signal line CP_CTL is used as a power supply voltage for operating the balloon latch circuit in the R-FF circuit during a standby period in which supply of the power supply voltage VDD is cut off.

The power supply line VDC_L and the signal line CP_CTL are formed of metal lines arranged on the semiconductor chip. Since the power supply line VDC_L and the signal line CP_CTL are metal lines, they have low sheet resistance and it is possible to suppress the reduction in the transmitted voltage. In addition, as will be described later, the retention control signal CP_CT is made up of a plurality of control signals, and therefore the signal line CP_CTL is also made up of a plurality of signal lines.

### Graphics Unit GPU and Other Unit ETU

Since the graphics unit GPU and the other unit ETU are similar to the processor CPU, only the difference will be mainly described.

In the graphics unit GPU and the other unit ETU, logic circuits corresponding to the logic circuit CP_LG are denoted by reference signs GP_LG and ET_LG, memory devices corresponding to the memory device CP_RFF are denoted by reference signs GP_RFF and ET_RFF, and power supply lines corresponding to the power supply line VDC_L are denoted by reference signs VDG_L and VDE_L. In addition, the power supply lines VDG_L and VDE_L are connected to the power supply line VD_L via the power switch circuits PW_GP and PW_ET controlled to be switched on and off by first control signals (graphics-processor power control signal, other-unit power control signal) PD_GP and PD_ET output from the power supply manager PWM.

In the graphics unit GPU and the other unit ETU, the second control signals (retention control signal) supplied to the memory devices GP_RFF and ET_RFF are denoted by reference signs GP_CT and ET_CT, and the signal lines that transmit the second control signals are denoted by reference signs GP_CTL and ET_CTL. In the graphics unit GPU and the other unit ETU as well, voltages on the signal lines GP_CTL and ET_CTL are used as power supply voltages for operating the balloon latch circuits in the R-FF circuits provided in the memory devices GP_RFF and ET_RFF during the standby period.

### Control by Power Supply Manager PWM

FIG. 11 is a timing chart illustrating an operation of the semiconductor device CHP realized by the control of the power supply manager PWM. In order to reduce the current consumption (power consumption) of the semiconductor device CHP, the power supply manager PWM controls the operation of each circuit block in the semiconductor device CHP in accordance with predetermined rules. In FIG. 11, the horizontal axis represents time T and the vertical axis represents power consumption P. Here, as an example of the circuit block controlled by the power supply manager PWM, for example, the processor CPU illustrated in FIG. 10 will be described. Of course, the graphics unit GPU and the other unit ETU illustrated in FIG. 10 are also controlled by the power supply manager PWM in the same manner as the processor CPU.

In FIG. 11, the power supply manager PWM performs control such that the processor CPU operates while transitioning sequentially through a standby period STB_T, a wakeup period WKU_T, a restoration period RET_T, and an operation period RUN_T.

The power supply manager PWM sets the power switch circuit PW_CP to a non-conductive state by the processor power control signal PD_CP during the standby period STB_T (time t0 to t1). As a result, during the standby period STB_T, supply of the power supply voltage VDD to the logic circuit CP_LG and the memory device CP_RFF in the processor CPU is cut off. On the other hand, during the standby period STB_T, a voltage on the signal line CP_CTL is supplied as a power supply voltage to the balloon latch circuit in the memory device CP_RFF. Accordingly, the balloon latch circuit retains the data saved in advance during the standby period STB_T.

Next, at time t1, the power supply manager PWM activates the processor CPU. That is, the power supply manager PWM sets the power switch circuit PW_CP to a conductive state by the processor power control signal PD_CP. As a result, the power supply voltage VDD is supplied via the power switch circuit PW_CP to the logic circuit CP_LG and the memory device CP_RFF in the processor CPU, and the logic circuit CP_LG and the memory device CP_RFF start operation, thereby transitioning to the wakeup period WKU_T (time t1 to t2).

During the standby period STB_T, since supply of the power supply voltage to the parts of the memory device CP_RFF other than the balloon latch circuit is cut off, the data held in the memory device CP_RFF is indefinite. In the restoration period RET_T (time t2 to t3) following the wakeup period WKU_T, the power supply manager PWM restores the data retained in the balloon latch circuit to the memory device CP_RFF by the retention control signal CP_CT. As a result, at time t3, the processor CPU is restored to a state prior to time t0 at which the processor CPU transitioned to the standby period STB_T.

During the operation period RUN_T that starts from time t3, the processor CPU resumes operation from the restored state, and executes a predetermined function during a function period FNC_T. In a saving period STP_T following the function period FNC_T in the operation period RUN_T, the power supply manager PWM saves the data held in the memory device CP_RFF to the balloon latch circuit by the retention control signal CP_CT. As a result, the data generated in the function period FNC_T is saved to the balloon latch circuit prior to the following standby period STB_T that starts at time t4, and the data is retained in the balloon latch circuit during the standby period STB_T that starts at time t4.

In the standby period STB_T, since supply of the power supply voltage VDD to the memory device CP_RFF other than the logic circuit CP_LG and the balloon latch circuit is cut off, the current consumption of the processor CPU can be reduced and the current consumption of the semiconductor device CHP can be reduced. In addition, since the data saved to the balloon latch circuit is restored in the restoration period RET_T, the time to set the data in the memory device CP_RFF can be shortened.

### Specific Configuration of Semiconductor Device

FIG. 1 is a block diagram illustrating a specific example of the semiconductor device according to the first embodiment. FIG. 1 illustrates an example in which the processor CPU, the graphics unit GPU, and the other unit ETU are made up of a plurality of standard cells STD and a plurality of cells (cells of R-FF circuit). When the semiconductor chip is viewed in plan view, the plurality of standard cells STD and the plurality of cells RFF are arranged in a mixed manner on the semiconductor chip and connected to each other as illustrated in FIG. 1.

### Processor CPU

The logic circuit CP_LG (FIG. 10) constituting the processor CPU is realized by combining the plurality of standard cells STD, and the memory device CP_RFF (FIG. 10) is realized by the plurality of R-FF circuits RFF. The standard cells STD and the R-FF circuits RFF are each made up of, for example, a plurality of P channel field effect transistors (hereinafter referred to also as P type transistors) and a plurality of N channel field effect transistors (hereinafter referred to also as N type transistors).

Here, the plurality of P type transistors is formed in an N channel semiconductor well (hereinafter referred to also as N type semiconductor well) N-well formed on a substrate (not illustrated) of the semiconductor chip. Similarly, the plurality of N type transistors is formed in a P channel semiconductor well (hereinafter referred to also as P type semiconductor well) P-well formed on the substrate of the semiconductor chip.

In FIG. 1, regions of the N type semiconductor well N-well and the P type semiconductor well P-well when viewed in plan view are surrounded by dashed lines. As will be described later with reference to drawings, P type semiconductor regions functioning as source and drain of a P type transistor are formed in the N type semiconductor well N-well, and N type semiconductor regions functioning as source and drain of an N type transistor are formed in the P type semiconductor well P-well. In addition, the N type semiconductor well N-well functions as a back gate of the P type transistor, and the P type semiconductor well P-well functions as a back gate of the N type transistor.

The R-FF circuit RFF is realized by connecting a plurality of P type transistors and a plurality of N type transistors. Similarly, in the standard cell STD as well, a desired logic circuit is constituted by connecting a plurality of P type transistors and a plurality of N type transistors. The logic circuit CP_LG illustrated in FIG. 10 is realized by connecting the logic circuits made up of the standard cells STD.

In FIG. 1, the line VDC_L depicted on the N type semiconductor well N-well indicates the power supply line described in FIG. 10, and the line GD_L depicted on the P type semiconductor well P-well indicates the ground line described in FIG. 10. As described in FIG. 10, the power supply lines VDC_L are arranged in a mesh pattern (VDC_L mesh) when viewed in plan view. In FIG. 1, one power supply line VDC_L depicted on the N type semiconductor well N-well indicates one of the power supply lines VDC_L arranged in a mesh pattern.

As illustrated in FIG. 10, the power supply lines VDC_L arranged in a mesh pattern are connected to the power supply line VD_L via the power switch circuit PW_CP. In FIG. 1, the power switch circuit PW_CP is made up of a P type transistor PW1. That is, a source-drain path of the P type transistor PW1 is connected in series between the power supply lines VD_L and VDC_L. The processor power control signal PD_CP is supplied from the power supply manager PWM to the gate of this P type transistor PW1.

In addition, the processor retention control signal CP_CT and a processor clock signal CLK:CPU are supplied from the power supply manager PWM to the processor CPU. The retention control signal CP_CT is supplied from the power supply manager PWM to the processor CPU via the signal line CP_CTL illustrated in FIG. 10. As will be described later, the retention control signal CP_CT is made up of a processor saving control signal CP_CT:s and a processor restoration control signal CP_CT:r, and these signals are supplied via different signal lines, respectively.

As will be described in detail later with reference to drawings, a power supply voltage (hereinafter referred to also as a retention power supply voltage) VDR_C generated based on the power supply voltage VDD on the power supply line DVC_L and/or a voltage on a signal line that transmits the retention control signal CP_CT is supplied to the N type semiconductor well N-well. In addition, the ground voltage GND on the connected ground line GD_L is supplied to the P type semiconductor well P-well.

### Graphics Unit GPU and Other Unit ETU

Since the graphics unit GPU and the other unit ETU are similar to the processor CPU, only the difference will be mainly described.

In the graphics unit GPU and the other unit ETU, power supply lines are denoted by VDG_L and VDE_L. In addition, the power switch circuits PW_GP and PW_ET illustrated in FIG. 10 are made up of P type transistors PW2 and PW3. Further, a graphics-unit power control signal and an other-unit power control signal supplied from the power supply manager PWM to gates of the P type transistors PW2 and PW3 are denoted by reference signs PD_GP and PD_ET.

In addition, a graphics-unit retention control signal and an other-unit retention control signal supplied from the power supply manager PWM to the graphics unit GPU and the other unit ETU are denoted by reference signs GP_CT and ET_CT. Lines that transmit the retention control signals GP_CT and ET_CT are the signal lines GP_CTL and ET_CTL illustrated in FIG. 10. Further, clock signals supplied from the power supply manager PWM to the graphics unit GPU and the other unit ETU are denoted by reference signs CLK:GPU and CLK:ETU. Reference signs VDR_G and VDR_E denote retention power supply voltages supplied to the N type semiconductor wells N-well of the graphics unit GPU and the other unit ETU.

The retention control signal GP_CT is made up of a graphics-unit saving control signal GP_CT:s and a graphics-unit restoration control signal GP_CT:r. Similarly, the retention control signal ET_CT is made up of an other-unit saving control signal ET_CT:s and an other-unit restoration control signal ET_CT:r.

### Power Supply Manager PWM

The power supply manager PWM includes a power supply management unit PMU, a clock generation circuit CLK_G, buffer circuits BPD, BCS, and BCR, and an AND circuit ANC1.

The power supply management unit PMU, the clock generation circuit CLK_G, the buffer circuits BPD, BCS, and BCR, and the AND circuit ANC1 are connected to the power supply line VD_L and the ground line GD_L, and operate using, as power supply voltages, the power supply voltage VDD and the ground voltage GND. Note that the ground line GD_L connected to the power supply management unit PMU, the clock generation circuit CLK_G, the buffer circuits BPD, BCS, and BCR, and the AND circuit ANC1 is omitted in FIG. 1.

The power supply management unit PMU outputs the power control signal, the retention control signal, and a clock gating signal CLK_GT for controlling the operation of the circuit blocks in the semiconductor device CHP in accordance with predetermined rules.

The power supply management unit PMU generates, as power control signals, 3-bit data corresponding one-to-one to each of the processor CPU, the graphics unit GPU, and the other unit ETU, and supplies the 3-bit data to the buffer circuit BPD. The buffer circuit BPD supplies the 3-bit data to the P type transistors PW1, PW2, and PW3 as the processor power control signal PD_CP, the graphics-unit power control signal PD_GP, and the other-unit power control signal PD_ET.

As described above, the retention control signal is made up of a saving control signal and a restoration control signal. The power supply management unit PMU generates, as the saving control signal of the retention control signal, 3-bit data corresponding one-to-one to each of the processor CPU, the graphics unit GPU, and the other unit ETU, and supplies the 3-bit data to the buffer circuit BCS. The buffer circuit BCS supplies the 3-bit data to the processor CPU, the graphics unit GPU, and the other unit ETU as the processor saving control signal CP_CT:s, the graphics-unit saving control signal GP_CT:s, and the other-unit saving control signal ET_CT:s.

In addition, the power supply management unit PMU generates, as the restoration control signal of the retention control signal, 3-bit data corresponding one-to-one to each of the processor CPU, the graphics unit GPU, and the other unit ETU, and supplies the 3-bit data to the buffer circuit BCR. The buffer circuit BCR supplies the 3-bit data to the processor CPU, the graphics unit GPU, and the other unit ETU as the processor restoration control signal CP_CT:r, the graphics-unit restoration control signal GP_CT:r, and the other-unit restoration control signal ET_CT:r.

The clock generation circuit CLK_G generates a clock signal CLK with a predetermined frequency. This clock signal CLK and the clock gating signal CLK_GT are supplied to the AND circuit ANC1. The clock signals CLK:CPU, CLK:GPU, and CLK:ETU are supplied from the AND circuit ANC1 to the processor CPU, the graphics unit GPU, and the other unit ETU. The AND circuit ANC1 functions to fix the clock signals CLK: CPU, CLK:GPU, and CLK:ETU to a low level during the period in which a clock gating signal CLK_GT is at a low level.

By the power supply management unit PMU outputting the power control signal, the retention control signal, and the clock gating signal CLK_GT in accordance with predetermined rules, the control described in the section of Control by Power Supply Manager PWM above is realized in the semiconductor device CHP.

The power supply manager PWM illustrated in FIG. 1 is also realized by combining a plurality of P type transistors and a plurality of N type transistors. The P type transistors and the N type transistors that realize the power supply manager PWM are also formed in the N type semiconductor well and the P type semiconductor well, for example, similarly to the P type transistors and the N type transistors constituting the standard cell STD. Here, the plurality of P type transistors constituting the power supply manager PWM and the P type transistors PW1 to PW3 constituting the power switch circuit are formed in an N type semiconductor well electrically separated from the N type semiconductor well N-well in which the P type transistors of the standard cell STD and the R-FF circuit RFF constituting the processor CPU and the like are formed. Accordingly, a voltage different from that of the P type transistors constituting the processor CPU and the like can be applied to the back gates of the P type transistors constituting the power supply manager PWM.

### R-FF Circuit

As illustrated in FIG. 10 and FIG. 11, the R-FF circuit RFF constituting the memory device (for example, CP_RFF) saves the data generated in the logic circuit (for example, CP_LG) during the operation period RUN_T, and retains the saved data during the standby period STB_T in which the power supply is cut off. After the power supply is restored, the logic circuit CP_LG resumes the processing using the data retained in the R-FF circuit RFF. In the semiconductor device according to the first embodiment, the retention power supply voltage VDR_C is supplied to the R-FF circuit RFF using the signal line (for example, CP_CTL) during the standby period STB_T such that the R-FF circuit RFF can retain the data even in the standby period STB_T in which the power supply is cut off.

As illustrated in FIG. 1, each of the processor CPU, the graphics unit GPU, and the other unit ETU includes the plurality of R-FF circuits RFF. These R-FF circuits RFF have similar configurations and operate in the same way. Therefore, one R-FF circuit RFF provided in the processor CPU is taken as an example, and the configuration and operation thereof will be described here.

### Terminals of R-FF Circuit

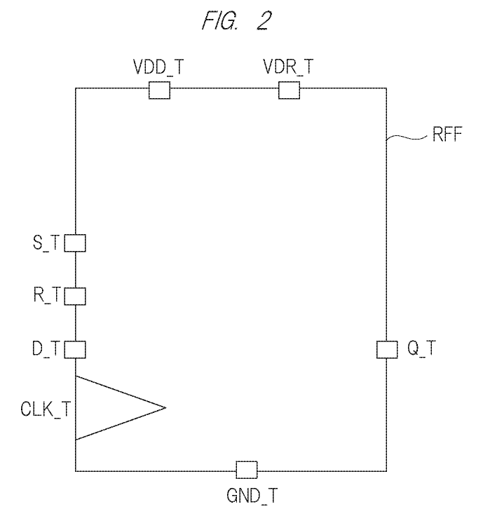

The R-FF circuit RFF according to the first embodiment is made up of one unit cell. FIG. 2 is a diagram for describing the R-FF circuit according to the first embodiment. The cell of the R-FF circuit RFF has, as terminals, a power supply terminal VDD_T, a terminal for retention power supply voltage (retention power supply terminal) VDR_T (to which VDR_C in FIG. 1 is supplied), a ground power supply terminal GND_T, a data input terminal D_T, and a data output terminal Q_T. Furthermore, the cell of the F-FF circuit RFF has a clock terminal CLK_T, a control terminal S_T to which a saving control signal (CP_CT:s in FIG. 1) is supplied, and a control terminal R_T to which a restoration control signal (CP_CT:r in FIG. 1) is supplied.

When the R-FF circuit is viewed as a cell, each terminal illustrated in FIG. 2 can be regarded also as a symbol of the cell. In addition, the power supply terminal VDD_T can be regarded as a power supply terminal subject to power cut-off, and the retention power supply terminal VDR_T can be regarded as a power supply terminal not subject to power cut-off.

### Configuration of R-FF Circuit

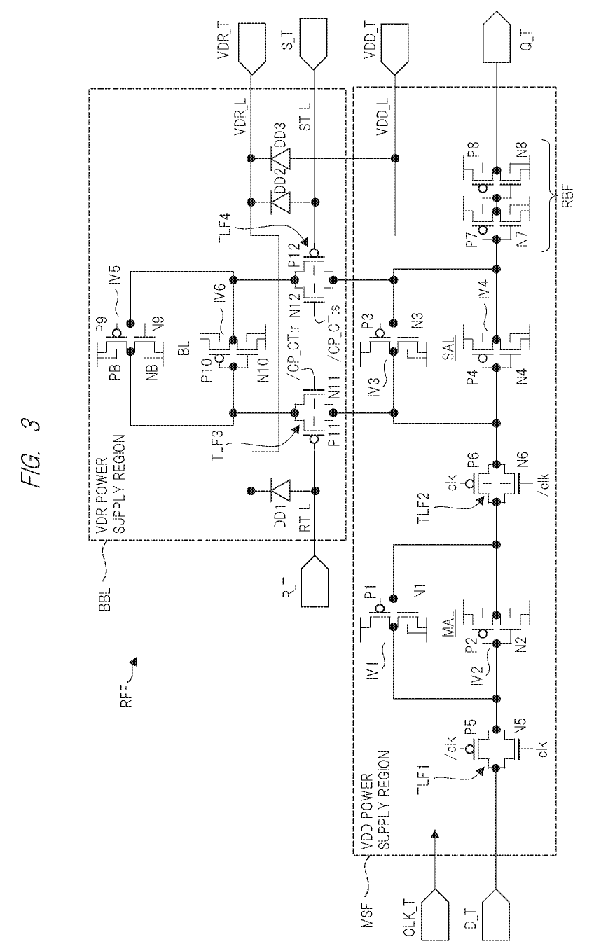

FIG. 3 is a circuit diagram illustrating a configuration of the R-FF circuit according to the first embodiment. The R-FF circuit RFF is made up of a master-slave flip-flop circuit (hereinafter simply referred to also as flip-flop circuit) MSF and a balloon latch circuit (hereinafter referred to also as latch circuit) BBL. The flip-flop circuit MSF is arranged in a power supply region (VDD power supply region) to which power is supplied from the power supply line VDC_L (FIG. 1) connected to the power supply terminal VDD_T in the semiconductor device, and operates using the power supply voltage VDD from the power supply line VDC_L as a power supply voltage. On the other hand, the latch circuit BBL is arranged in a power supply region (VDR power supply region) to which the retention power supply voltage VDR_C (FIG. 1) on the signal line connected to the retention power supply terminal VDR_T is supplied, and operates using the retention power supply voltage VDR_C as a power supply voltage.

### Flip-Flop Circuit

The flip-flop circuit MSF includes a master latch MAL, a slave latch SAL, a transfer switch (transfer circuit) TLF1 connected between the input terminal D_T and an input of the master latch MAL, a transfer switch TLF2 connected between an output of the master latch MAL and an input of the slave latch SAL, and a buffer circuit RBF connected between an output of the slave latch SAL and the output terminal Q_T.

As illustrated in FIG. 3, the master latch MAL includes an inverter circuit IV1 made up of a P type transistor P1 and an N type transistor N1 and an inverter circuit IV2 made up of a P type transistor P2 and an N type transistor N2. Inputs and outputs of the inverter circuits IN1 and IN2 are cross-connected to each other, thereby forming a latch circuit.

The slave latch SAL includes an inverter circuit IV3 made up of a P type transistor P3 and an N type transistor N3 and an inverter circuit IV4 made up of a P type transistor P4 and an N type transistor N4, similarly to the master latch MAL. Inputs and outputs of the inverter circuits IN3 and IN4 are also cross-connected to each other, thereby forming a latch circuit.

The transfer switch TLF1 (TLF2) includes a P type transistor P5 (P6) and an N type transistor N5 (N6) whose source-drain paths are connected in parallel to each other. Here, a clock signal /clk is supplied to gates of the P type transistor P5 and the N type transistor N6, and a clock signal clk is supplied to gates of the P type transistor P6 and the N type transistor N5. The clock signals clk and /clk are clock signals generated based on the clock signal CLK:CPU supplied to the clock terminal CLK_T. That is, the clock signal clk is a clock signal in phase with the clock signal CLK:CPU, and the clock signal /clk is a clock signal having an inverted phase with respect to the clock signal CLK:CPU.

Accordingly, when the clock signal CLK:CPU becomes a high level, the clock signal clk becomes a high level and the clock signal /clk becomes a low level. On the other hand, when the clock signal CLK:CPU becomes a low level, the clock signal clk becomes a low level and the clock signal /clk becomes a high level.

As a result, when the clock signal CLK:CPU becomes a high level, the transfer switch TLF1 is set to a conductive state, and data (high level or low level) at the input terminal D_T is transmitted to the master latch MAL via the transfer switch TLF1, whereby the data is captured in the master latch MAL. At this time, the transfer switch TLF2 is set to a non-conductive state, the slave latch SAL is separated from the master latch MAL, and data held in the slave latch SAL continues to be output from the output terminal Q_T via a buffer circuit RBF made up of P type transistors P7 and P8 and N type transistors N7 and N8.

Next, when the clock signal CLK:CPU transitions from a high level to a low level, the transfer switch TLF1 is set to a non-conductive state, and the master latch MAL is separated from the input terminal D_T and retains the captured data. At this time, the transfer switch TLF2 is set to a conductive state, and the data held in the master latch MAL is transmitted to the slave latch SAL and captured in the slave latch SAL. The data captured in the slave latch SAL is output from the output terminal Q_T via the buffer circuit RBF.

Sources of the P type transistors P1 to P4, P7, and P8 constituting the flip-flop circuit MSF are connected to a power supply line VDD_L, and sources of the N type transistors N1 to N4, N7, and N8 are connected to the ground line GD_L (FIG. 1) via the ground power supply terminal GND_T (FIG. 2). As a result, the flip-flop circuit MSF operates using, as power supply voltages, the power supply voltage VDD supplied to the power supply terminal VDD_T and the ground voltage GND supplied to the ground power supply terminal GND_T.

Back gates of the P type transistors P1 to P8 constituting the flip-flop circuit MSF are connected to a retention power supply line VDR_L connected to the retention power supply terminal VDR_T, and back gates of the N type transistors N1 to N8 are connected to the ground line GD_L. In FIG. 3, in order to prevent the drawing from being complicated, only a back gate of a P type transistor P9 is denoted by a reference sign PB, and similarly, only a back gate of an N type transistor N9 is denoted by a reference sign NB.

### Latch Circuit

The latch circuit BBL includes the balloon latch BL, two transfer switches TLF3 and TLF4 (for restoration and saving) connecting the balloon latch BL and the slave latch SAL in the flip-flop circuit MSF, and diodes DD1 to DD3 constituting a unidirectional circuit.

As illustrated in FIG. 3, the balloon latch BL includes an inverter circuit IV5 made up of the P type transistor P9 and the N type transistor N9 and an inverter circuit IV6 made up of a P type transistor P10 and an N type transistor N10. Inputs and outputs of the inverter circuits IV5 and IV6 are cross-connected to each other, thereby forming a latch circuit.

The restoration transfer switch TLF3 includes a P type transistor P11 and an N type transistor N11 whose source-drain paths are connected in parallel to each other. Here, a gate of the P type transistor P11 is connected to the control terminal R_T by a signal line RT_L. The restoration control signal CP_CT:r (FIG. 1) supplied to the control terminal R_T is supplied to the gate of the P type transistor P11 via the signal line RT_L. Also, a restoration control signal /CP_CT:r having an inverted phase with respect to the restoration control signal CP_CT:r is supplied to a gate of the N type transistor N11 via a signal line (not illustrated).

The saving transfer switch TLF4 also includes a P type transistor P12 and an N type transistor N12 whose source-drain paths are connected in parallel to each other, similarly to the restoration transfer switch TLF3. Here, a gate of the P type transistor P12 is connected to the control terminal S_T via a signal line ST_L. The saving control signal CP_CT:s (FIG. 1) supplied to the control terminal S_T is supplied to the gate of the P type transistor P12 via the signal line ST_L. Also, a saving control signal /CP_CT:s having an inverted phase with respect to the saving control signal CP_CT:s is supplied to a gate of the N type transistor N12 via a signal line (not illustrated).

An anode of the diode DD1 (first unidirectional circuit) is connected to the signal line RT_L, and a cathode thereof is connected to the retention power supply line VDR_L. Also, an anode of the diode (first unidirectional circuit) DD2 is connected to the signal line ST_L, and a cathode thereof is connected to the retention power supply line VDR_L. Furthermore, an anode of the diode DD3 (second unidirectional circuit) is connected to the power supply line VDD_L, and a cathode thereof is connected to the retention power supply line VDR_L.

Sources and back gates PB of the P type transistors P9 and P10 constituting the balloon latch BL are connected to the retention power supply line VDR_L, and sources and back gates NB of the N type transistors N9 and N10 are connected to the ground line GD_L (FIG. 1) via the ground power supply terminal GND_T (FIG. 2). As a result, the balloon latch BL operates using, as power supply voltages, the retention power supply voltage VDR_C on the retention power supply line VDR_L and the ground voltage GND.

Note that back gates of the P type transistors P11 and P12 constituting the transfer switches TLF3 and TLF4 are also connected to the retention power supply line VDR_L, and back gates of the N type transistors N11 and N12 are connected to the ground line GD_L.

In the R-FF circuit RFF according to the first embodiment, the voltage on the signal lines RT_L and ST_L supplied via the diodes DD1 and DD2 is supplied to the retention power supply line VDR_L during the standby period STB_T (FIG. 11). The balloon latch BL operates so as to retain data using, as power supply voltages, the retention power supply voltage VDR_C on the retention power supply line VDR_L and the ground voltage GND during the standby period STB_T. Accordingly, it becomes possible to eliminate the need to arrange the power supply line which supplies the retention power supply voltage to the retention power supply terminal VDR_T of the R-FF circuit RFF during the standby period STB_T (FIG. 11) in a mesh pattern on the semiconductor chip.

### Power Supply Configuration Using Signal Line

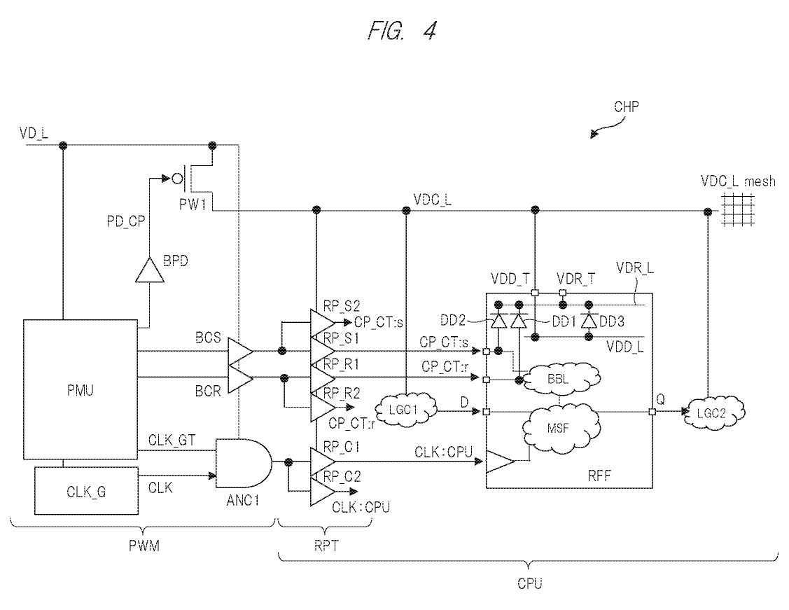

FIG. 4 is a diagram for describing the semiconductor device according to the first embodiment. The supply of the retention power supply voltage VDR_C using signal lines will be described with reference to FIG. 4. Since FIG. 4 is similar to FIG. 1, only the difference will be mainly described.

FIG. 4 illustrates only the processor CPU, and the graphics unit GPU and the other unit ETU illustrated in FIG. 1 are omitted. In addition, even in the processor CPU, only one R-FF circuit RFF and parts relating to this R-FF circuit RFF are illustrated in FIG. 4. In the processor CPU, other R-FF circuits not illustrated in FIG. 4 and parts relating thereto are similar to those illustrated in FIG. 4. Furthermore, other R-FF circuits and parts relating thereto arranged in the graphics unit GPU and the other unit ETU omitted in FIG. 4 are also similar to those illustrated in FIG. 4.

In FIG. 4, since the power supply manager PWM is similar to that described in FIG. 1, a detailed description thereof will be omitted. As described in FIG. 1, the power supply manager PWM outputs the power control signal PD_CP, the clock signal CLK:CPU, the saving control signal CP_CT:s, and the restoration control signal CP_CT:r to the P type transistor PW1 and the processor CPU.

As illustrated in FIG. 1, the R-FF circuits RFF and the standard cells STD are arranged in a mixed manner in the processor CPU. FIG. 4 illustrates logic circuits LGC1 and LGC2 configured by combining one R-FF circuit RFF made up of one cell and a plurality of standard cells STD.

Also, the processor CPU includes a repeater circuit RPT configured to buffer the retention control signal and the clock signal from the power supply manager PWM and supply the buffered signals to the R-FF circuit. The repeater circuit RPT is made up of a plurality of unit repeater circuits. The plurality of R-FF circuits provided in the processor CPU is divided into a plurality of groups, and the unit repeater circuit is assigned to each of the groups. Although not particularly limited, FIG. 4 illustrates two unit repeater circuits RP_C1, RP_C2, RP_S1, RP_S2, RP_R1, and RP_R2 for each of the clock signal CLK:CPU, the saving control signal CP_CT:s, and the restoration control signal CP_CT:r.

The R-FF circuit RFF illustrated in FIG. 4 is the same as the R-FF circuit described in FIG. 3. In FIG. 4, however, the detailed configuration of the flip-flop circuit MSF and the latch circuit BBL is omitted. Note that the diodes DD1 to DD3, the retention power supply line VDR_L, and the power supply line VDD_L illustrated in FIG. 4 are the same as those described in FIG. 3.

In FIG. 3, the saving control signal output from the buffer circuit BCS is supplied to the control terminal S_T (FIG. 3) of the R-FF circuit RFF as the saving control signal CP_CT:s via the unit repeater circuit RP_S1. Also, the saving control signal output from the buffer circuit BCS is supplied to the control terminal R_T (FIG. 3) of the R-FF circuit RFF as the restoration control signal CP_CT:r via the unit repeater circuit RP_R1. Furthermore, the clock signal output from the AND circuit ANC1 is supplied to the clock terminal of the R-FF circuit RFF as the clock signal CLK:CPU via the unit repeater circuit RP_C1.

### Unit Repeater Circuit

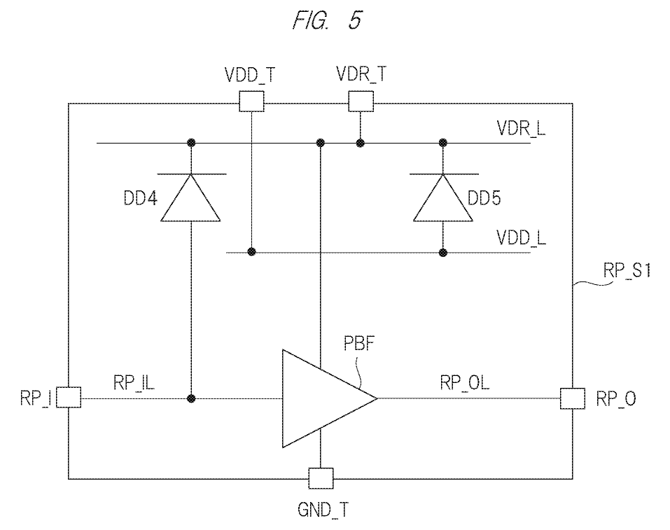

Since a plurality of unit repeater circuits constituting the repeater circuit RPT has the same configuration, one unit repeater circuit RP_S1 is described as an example. FIG. 5 is a block diagram illustrating a configuration of the unit repeater circuit according to the first embodiment.

Although not particularly limited, in the first embodiment, the unit repeater circuit RP_S1 is made up of the standard cell STD in the processor CPU illustrated in FIG. 1.

The unit repeater circuit RP_S1 has the power supply terminal VDD_T, the retention power supply terminal VDR_T, the ground power supply terminal GND_T, an input terminal RP_I, and an output terminal RP_O.

As illustrated in FIG. 5, the unit repeater circuit RP_S1 includes a buffer circuit PBF, diodes DD4 and DD5 constituting a unidirectional circuit, the retention power supply line VDR_L, and the power supply line VDD_L. An input terminal of the buffer circuit PBF is connected to the input terminal RP_I via a signal line RP_IL, and an output terminal thereof is connected to the output terminal RP_O via a signal line RP_OL. The buffer circuit PBF is connected to the retention power supply line VDR_L and the ground voltage terminal GND_T, and operates using, as power supply voltages, the power supply voltage on the retention power supply line VDR_L and the ground voltage GND. The buffer circuit PBF is made up of two inverter circuits connected in series (inverter circuit made up of P type transistor P7 and N type transistor N7 and inverter circuit made up of P type transistor P8 and N type transistor N8), for example, similarly to the buffer circuit RBF illustrated in FIG. 3. In this case, the retention power supply line VDR_L is connected to the source of the P type transistor (P7, P8) and the ground power supply terminal GND_T is connected to the source of the N type transistor (N7, N8).

As illustrated in FIG. 5, the retention power supply line VDR_L is connected to a cathode of the diode DD4, and the signal line RP_IL is connected to an anode of the diode DD4. Also, the retention power supply line VDR_L is connected to the retention power supply terminal VDR_T. Furthermore, the retention power supply line VDR_L is connected to a cathode of the diode DD5, and the power supply line VDD_L is connected to an anode of the diode DD5. Also, the power supply line VDD_L is connected to the power supply terminal VDD_T.

The power supply terminal VDD_T of the unit repeater circuit RP_S1 is connected to the power supply line VDC_L illustrated in FIG. 4. Also, the saving control signal is supplied from the buffer circuit BCR illustrated in FIG. 4 to the input terminal RP_I of the unit repeater circuit RP_S1, and the saving control signal CP_CT:s is supplied from the output terminal RP_O of the unit repeater circuit RP_S1 to the control terminal S_T (FIG. 3) of the R-FF circuit RFF.

During a period in which the P type transistor PW1 is set to a conductive state, the power supply voltage VDD is supplied to the power supply line VDC_L illustrated in FIG. 4 and to the power supply line VDD_L via the power supply terminal VDD_T of the unit repeater circuit. Accordingly, the power supply voltage VDD is supplied to the retention power supply line VDR_L via the diode DD5, and the buffer circuit PBF supplies the saving control signal CP_CT:s at a high level (voltage on the retention power supply line VDR_L) or low level (ground voltage GND) to the R-FF circuit RFF according to the saving control signal supplied to the input terminal RP_I.

On the other hand, during a period such as the standby period STB_T (FIG. 11), that is, a period in which the P type transistor PW1 is set to a non-conductive state, the saving control signal from the buffer circuit BCR is at a high level (power supply voltage VDD on the power supply line VD_L), and a voltage on the signal line RP_IL is also at a high level (VDD). Accordingly, the power supply voltage VDD is supplied to the retention power supply line VDR_L via the diode DD4, and the buffer circuit PBF supplies the saving control signal CP_CT:s at a high level (voltage on the retention power supply line VDR_L) to the control terminal S_T (FIG. 3) of the R-FF circuit RFF according to the high level of the saving control signal supplied to the input terminal RP_I.

In the R-FF circuit RFF, as illustrated in FIG. 3 and FIG. 4, the high level of the saving control signal CP_CT:s supplied to the control terminal S_T is supplied to the retention power supply line VDR_L in the R-FF circuit via the diode DD2, and to sources of the P type transistors P9 and P10 constituting the balloon latch BL. As a result, the balloon latch BL can retain data even during the standby period STB_T.

Here, the unit repeater circuit RP_S1 has been described as an example, but the same applies to the unit repeater circuit RP_R1 to which the restoration control signal is supplied from the power supply manager PWM and which supplies the restoration control signal CP_CT:r to the control terminal R_T of the R-FF circuit.

That is, the R-FF circuit RFF can retain the data saved in advance even when the power supply line which supplies the retention power supply voltage to the retention power supply terminal VDR_T of the R-FF circuit during the standby period STB_T (FIG. 11) is not arranged in a mesh pattern on the semiconductor chip.

FIG. 5 illustrates the example in which the buffer circuit BCR constituting the unit repeater circuit operates using the voltage on the retention power supply line VDR_L as a power supply voltage, but the present invention is not limited to this. For example, when the unit repeater circuit is arranged in a region close to the power supply line VD_L, the buffer circuit BCR may operate using the voltage on the power supply line VD_L as a power supply voltage.

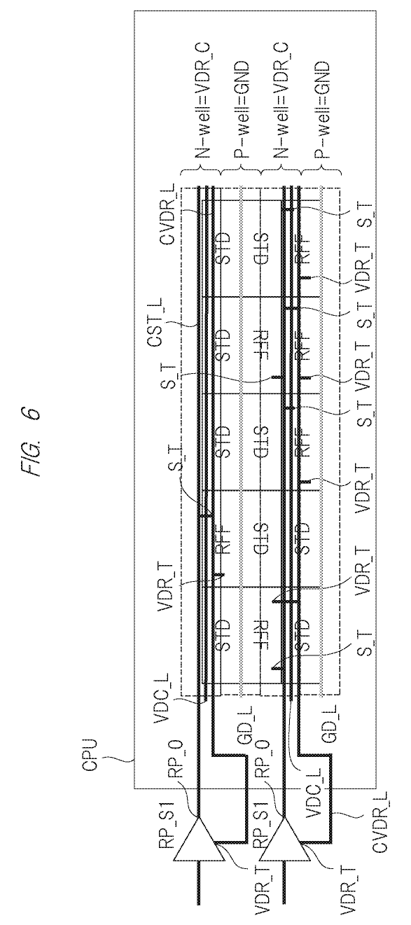

FIG. 6 is a diagram illustrating a relationship between the unit repeater circuit and the R-FF circuit according to the first embodiment. FIG. 6 is similar to FIG. 1, and FIG. 6 illustrates only a part of the processor CPU illustrated in FIG. 1 and a part of the unit repeater circuit RP_S1.

In FIG. 6, CST_L denotes a signal line that connects the output terminal RP_O of one unit repeater circuit RP_S1 and the control terminal S_T of one or more R-FF circuits. By this signal line CST_L, supply of the saving control signal CP_CT:s and, for example, supply of the power supply voltage during the standby period STB_T are performed for one or more R-FF circuits. In FIG. 6, CVDR_L denotes a power supply line that connects the retention power supply terminal VDR_T of one unit repeater circuit RP_S1 and the retention power supply terminal VDR_T of one or more R-FF circuits. The power supply line CVDR_L will be described later, and therefore is omitted here.

Although not illustrated in FIG. 6, a signal line (conveniently referred to as CRT_L) that connects the output terminal RP_O of the unit repeater circuit RP_R1 and the control terminal R_T of one or more R-FF circuits is also arranged in the same manner as the signal line CST_L. The signal line CRT_L and the signal line CST_L illustrated in FIG. 6 constitute the signal line CP_CTL illustrated in FIG. 10.

### Operation of Latch Circuit

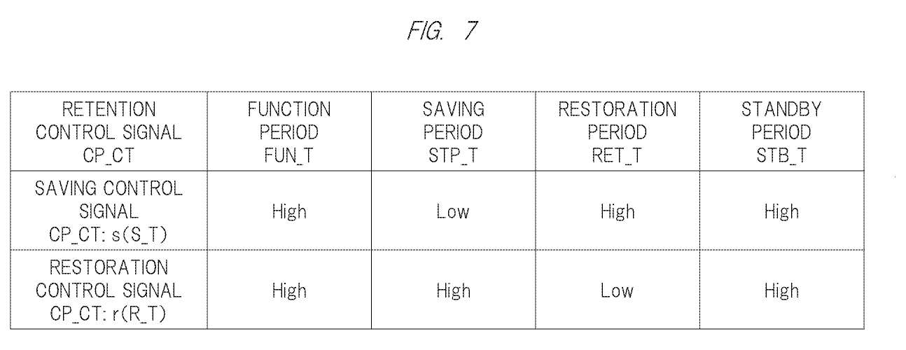

FIG. 7 is a truth table for describing an operation of the latch circuit according to the first embodiment. Next, the operation of the latch circuit BBL according to the first embodiment will be described with reference to FIG. 11, FIG. 3, FIG. 4, FIG. 6, and FIG. 7.

The transfer switch TLF3 in the latch circuit BBL illustrated in FIG. 3 is set to a non-conductive state when the restoration control signal CP_CT:r supplied to the control terminal R_T is at a high level (High), and is set to a conductive state when the restoration control signal CP_CT:r is at a low level (Low). Similarly, the transfer switch TLF4 in the latch circuit BBL is set to a non-conductive state when the saving control signal CP_CT:s supplied to the control terminal S_T is at a high level (High), and is set to a conductive state when the saving control signal CP_CT:s is at a low level (Low).

The power supply manager PWM sets the saving control signal CP_CT:s and the restoration control signal CP_CT:r to a high level during the function period FNC_T illustrated in FIG. 11. Also, the power supply manager PWM sets the saving control signal CP_CT:s to a low level and sets the restoration control signal CP_CT:r to a high level during the saving period STP_T (FIG. 11). Furthermore, the power supply manager PWM sets the saving control signal CP_CT:s to a high level and sets the restoration control signal CP_CT:r to a low level during the restoration period RET_T (FIG. 11). Also, power supply manager PWM sets the saving control signal CP_CT:s and the restoration control signal CP_CT:r to a high level during the standby period STB_T (FIG. 11).

During the function period FNC_T, the clock signal CLK:CPU output from the power supply manager PWM changes at a predetermined cycle. As a result, data D generated in the logic circuit LGC1 during the function period FNC_T is captured in the flip-flop circuit MSF of the R-FF circuit, and the data D is supplied from the flip-flop circuit MSF to the logic circuit LGC2. By supplying the data D from the logic circuit LGC1 to the logic circuit LGC2, a predetermined function is realized. Since the transfer switches TLF3 and TLF4 are set to a non-conductive state during the function period FNC_T, data transfer is not performed between the flip-flop circuit MSF and the latch circuit BBL.

Upon transitioning to the saving period STP_T, the saving control signal CP_CT:s becomes a low level, and therefore the transfer switch TLF4 is set to a conductive state. As a result, data held in the slave latch SAL of the flip-flop circuit MSF is transferred to the balloon latch BL via the transfer switch TLF4. At this time, the power supply voltage VDD is supplied to the power supply terminal VDD_T from the power supply line VD_L via the P type transistor PW1 constituting the power switch circuit and the power supply line VDC_L, and the restoration control signal CP_CT:r at a high level is supplied to the control terminal R_T. Therefore, voltages are supplied from the signal line RT_L and the power supply line VDD_L to the retention power supply line VDR_L via the diodes DD1 and DD3, and to sources and back gates PB of the P type transistors P9 and P10 constituting the balloon latch BL. That is, during the saving period STP_T, the balloon latch BL operates to capture and retain the data transferred from the transfer switch TLF4.

Upon transitioning from the saving period STP_T to the standby period STB_T, the P type transistor PW1 is set to a non-conductive state, and thus power supply to the power supply terminal VDD_T is stopped. On the other hand, at this time, both the restoration control signal CP_CT:r and the saving control signal CP_CT:s are at a high level, and therefore high-level voltages are supplied from the signal line RT_L and the signal line ST_L to the retention power supply line VDR_L via the diodes DD1 and DD2, and to the sources and the back gates PB of the P type transistors P9 and P10 constituting the balloon latch BL. That is, during the standby period STB_T, the balloon latch BL operates so as to retain the data captured in advance. In addition, during the standby period STB_T, both the restoration control signal CP_CT:r and the saving control signal CP_CT:s are at a high level, and therefore both the transfer switches TLF3 and TLF4 are set to a non-conductive state, so that the balloon latch BL and the slave latch SAL are separated from each other.

Next, upon transitioning to the restoration period RET_T, the restoration control signal CP_CT:r becomes a low level, and therefore the transfer switch TLF3 is set to a conductive state, so that the data retained in the balloon latch BL is supplied to the slave latch SAL via the transfer switch TLF3 and captured in the slave latch SAL. The data captured in the slave latch SAL is supplied to the logic circuit LGC2, whereby the processing is resumed.

During the restoration period RET_T, the power supply voltage VDD is supplied from the power supply line VD_L via the P type transistor PW1 and the power supply line VDC_L, and the saving control signal CP_CT:s at a high level is supplied to the control terminal S_T. Therefore, voltages on the signal line ST_L and the power supply line VDD_L are supplied to the retention power supply line VDR_L via the diode DD2 and the diode DD3, and power is supplied to the balloon latch BL.

For example, during the restoration period RET_T, the saving control signal CP_CT:s becomes a low level, and the restoration control signal CP_CT:r becomes a high level. Accordingly, the signal line RT_L becomes a high level, and the signal line ST_L becomes a low level. Both the signal lines RT_L and ST_L are connected to the retention power supply line VDR_L via the diodes DD1 and DD2, but since the diodes DD1 and DD2 are unidirectional elements, it is possible to prevent the change in the voltages on the signal lines ST_L and RT_L. The same applies to the restoration period RET_T.

### Diodes DD1 to DD5

Sizes of the diodes DD1 to DD5 are set in accordance with, for example, the current values required during the operation period RUN_T and the standby period STB_T illustrated in FIG. 11. For example, as illustrated in FIG. 6, the unit repeater circuit RP_S1 and the retention power supply terminal VDR_T of the R-FF circuit RFF may be connected by the power supply line CVDR_L, and the sizes of the respective diodes may be set so as to meet the required current values using the diodes DD4 and DD5 in the unit repeater circuit and the diodes DD1 to DD3 in the plurality of R-FF circuits.

Next, an example will be described in First Modification, but the diodes DD1 to DD5 may be formed of a semiconductor well constituting a semiconductor chip and a semiconductor region formed in the semiconductor well. In this case, the semiconductor well functions as a part of a power supply line that supplies a retention power supply voltage.

### First Modification

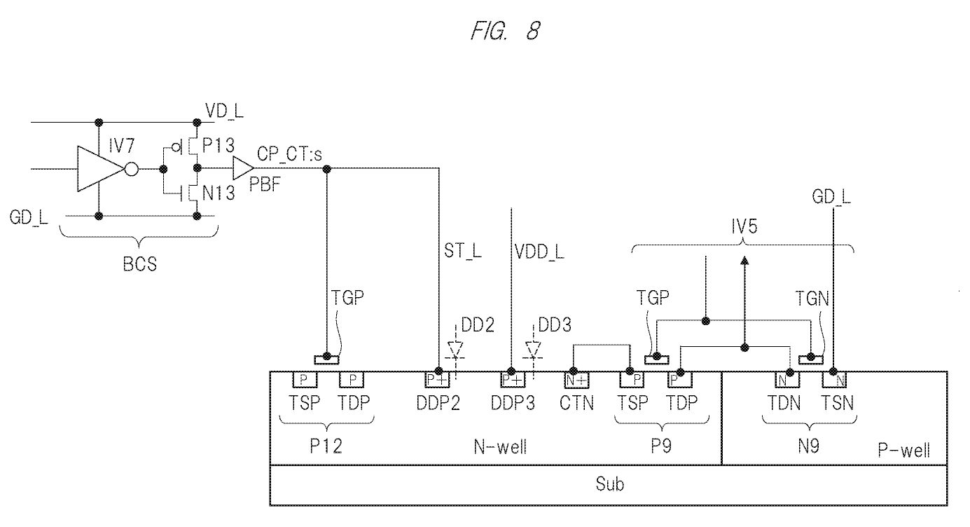

FIG. 8 is a schematic cross-sectional view for describing the first modification according to the first embodiment. As illustrated in FIG. 1, the N type semiconductor well and the P type semiconductor well are common to the plurality of standard cells STD and the plurality of cells of the R-FF circuits RFF. In the first modification, an example in which the P type semiconductor well forms a part of a retention power supply line will be described.

In FIG. 8, Sub denotes a substrate of a semiconductor chip. A plurality of P type transistors and diodes DD1 to DD5 are formed in the N type semiconductor well N-well formed on the substrate Sub, and a plurality of N type transistors is formed in the P type semiconductor well P-well formed on the substrate Sub. In FIG. 8, among the P type transistors and the N type transistors illustrated in FIG. 3, the P type transistors P9 and P12 and the N type transistor N9 are illustrated as examples, and further, among the diodes DD1 to DD5, the diodes DD2 and DD3 are illustrated as examples.

In FIG. 8, a reference sign TSP denotes P type semiconductor regions constituting sources of the P type transistors P9 and P12, a reference sign TDP denotes P type semiconductor regions constituting drains of the P type transistors P9 and P12, and a reference sign TGP denotes gate electrodes constituting gates of the P type transistors P9 and P12. As illustrated in FIG. 8, the gate electrodes constituting the gates of the P type transistors P9 and P12 are formed on the N type semiconductor well N-well, which functions as a back gate, via an insulating film (not illustrated) between the sources and drains of the P type transistors P9 and P12. Similarly, a reference sign TSN denotes an N type semiconductor region constituting a source of the N type transistor N9, a reference sign TDN denotes an N type semiconductor region constituting a drain of the N type transistor N9, and a reference sign TGN denotes a gate electrode constituting a gate of the N type transistor N9. The gate electrode constituting the gate of the N type transistor N9 is formed on the P type semiconductor well P-well, which functions as a back gate, via an insulating film (not illustrated) between the source and drain of the N type transistor N9.

As indicated by dashed lines, the diode DD2 is made up of a high-concentration P type semiconductor region (third semiconductor region) DDP2 formed in the N type semiconductor well N-well and the N type semiconductor well N-well. The P type semiconductor region DDP2 is connected to the buffer circuit BCS (see also FIG. 4) via the signal line ST_L (see also FIG. 3) and the buffer circuit PBF (see also FIG. 5). As illustrated in FIG. 8, the buffer circuit BCS includes a P type transistor P13 and an N type transistor N13 connected in series between the power supply line VD_L and the ground line GD_L and an inverter circuit IV7 configured to supply the saving control signal from the power supply management unit PMU to gates of the P type transistor P13 and the N type transistor N13.

Accordingly, when the saving control signal at a high level is output from the power supply management unit PMU, the P type transistor P13 becomes a conductive state, and the power supply voltage VDD on the power supply line VD_L is output from the buffer circuit BCS as the saving control signal CP_CT:s and supplied to the buffer circuit PBF constituting the unit repeater circuit. The buffer circuit PBF outputs a voltage corresponding to the supplied power supply voltage VDD to the P type semiconductor region DDP2 via the signal line ST_L. As a result, for example, during the standby period STB_T (FIG. 11), the voltage of the N type semiconductor well N-well becomes a voltage lower than that of the signal line ST_L by a threshold voltage of the diode DD2.

Similarly, as indicated by dashed lines, the diode DD3 is made up of a high-concentration P type semiconductor region (fourth semiconductor region) DDP3 formed in the N type semiconductor well N-well and the N type semiconductor well N-well. The P type semiconductor region DDP3 is connected to the power supply line VDC_L via the power supply line VDD_L (see also FIG. 3). As a result, when the power supply voltage VDD is supplied to the power supply line VDD_L via the P type transistor PW1 (FIG. 4) constituting the power switch circuit, the voltage of the N type semiconductor well N-well becomes a voltage lower than that of the power supply line VDD_L by a threshold voltage of the diode DD3.

The voltage of the N type semiconductor well N-well becomes a voltage of back gates of the P type transistors P9 and P12 formed in the N type semiconductor well N-well.

The P type semiconductor region TSP constituting the source of the P type transistor P9 is connected to a high-concentration N type semiconductor region CTN by a line. The N type semiconductor region CTN is formed in the N type semiconductor well N-well. Accordingly, the voltage of the N type semiconductor well N-well is supplied, as a power supply voltage, to the source of the P type transistor P9. That is, in the first modification, the N type semiconductor well N-well is used to supply, as a power supply voltage, a voltage corresponding to the power supply voltage VDD to the P type transistors constituting the balloon latch BL.

In contrast, the sources of the P type transistors P1, P2, P3, P4, P7, and P8 constituting the flip-flop circuit MSF (FIG. 3) are connected to the power supply line VDD_L, and the flip-flop circuit MSF is connected to the power supply line VDC_L via the power supply line VDD_L, and operates using, as a power supply voltage, the power supply voltage VDD on the power supply line VDD_L.

The sheet resistance of the N type semiconductor well N-well is higher than the sheet resistance of the metal lines constituting the power supply lines VDD_L, VDC_L, and VD_L, the retention power supply line VDR_L, the signal lines ST_L, RT_L, CP_CTL, GP_CTL, and ET_CTL, and the like illustrated in FIG. 3, FIG. 4, and FIG. 10. Therefore, the current value capable of being supplied in the N type semiconductor well N-well is limited. In the first modification, the N type semiconductor well N-well is used to supply the retention power supply voltage VDR when the balloon latch BL operates so as to retain data during the standby period STB_T. Since the N type semiconductor well N-well is used when retaining data and the current value to be flown is therefore limited, no problem arises even when the N type semiconductor well N-well is used as a retention power supply line.

When the P type transistor constituting the unit repeater circuit RP_S1 is formed in the same N type semiconductor well as the P type transistor constituting the balloon latch BL of the R-FF circuit RFF, the diode DD4 illustrated in FIG. 5 is necessary, whereas the diode DD5 is not necessarily provided. Also, since the N type semiconductor well N-well functions as the retention power supply line VDR_L, the retention power supply terminal VDR_T is unnecessary in the R-FF circuit RFF, and the power supply line CVDR_L illustrated in FIG. 6 is also unnecessary.

According to the first embodiment, even when the power supply lines formed of metal lines in a mesh pattern, which supply the power supply voltage during the standby period are not provided at the retention power supply terminal VDR_T of the R-FF circuit, the R-FF circuit can retain the data. Accordingly, it is possible to suppress an increase in the size of the semiconductor chip and an increase in the manufacturing cost.

### Second Embodiment

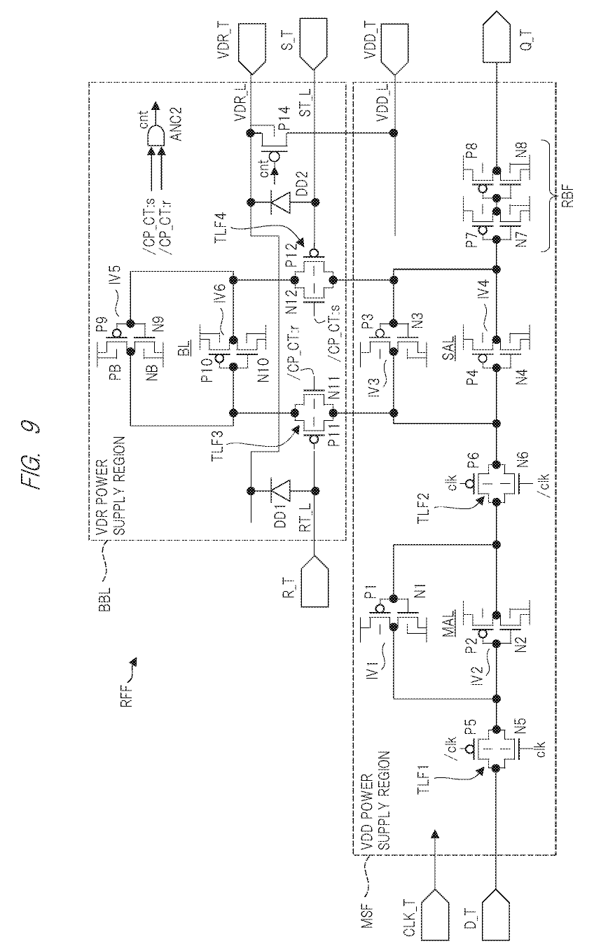

FIG. 9 is a circuit diagram illustrating a configuration of an R-FF circuit according to the second embodiment. Since FIG. 9 is similar to FIG. 3, only the difference will be mainly described. The difference is that the diode DD3 (FIG. 3) is eliminated and a P type transistor P14 whose source-drain path is connected between the retention power supply line VDR_L and the power supply line VDD_L is added in FIG. 9. Also, in FIG. 9, an AND circuit ANC2 configured to receive the saving control signal CP_CT:s and the restoration control signal CP_CT:r and supply an output signal cnt to a gate of the P type transistor P14 is added.

The power supply manager PWM (not illustrated) outputs the saving control signal CP_CT:s and the restoration control signal CP_CT:r illustrated in FIG. 7 during the function period FNC_T, the saving period STP_T, the restoration period RET_T, and the standby period STB_t illustrated in FIG. 11.

During the function period FUC_T, as illustrated in FIG. 7, the saving control signal CP_CT:s and the restoration control signal CP_CT:r become a high level, and therefore, the P type transistor P14 is set to a non-conductive state. However, the high level in the signal lines (ST_L and RT_L) configured to transmit the saving control signal CP_CT:s and the restoration control signal CP_CT:r is supplied to the retention power supply line VDR_L via the diodes DD1 and DD2, and further to the sources of the P type transistors P9 and P10 constituting the balloon latch BL. As a result, the balloon latch BL is set to an operating state. In other words, a current is supplied to the balloon latch BL via the diodes DD1 and DD2.

During the saving period STP_T, as illustrated in FIG. 7, the saving control signal CP_CT:s becomes a low level, and the restoration control signal CP_CT:r becomes a high level. Accordingly, the P type transistor P14 is set to a conductive state. As a result, a current is supplied to the balloon latch BL via both the diode DD1 and the P type transistor P14.

In addition, during the restoration period RET_T, as illustrated in FIG. 7, the saving control signal CP_CT:s becomes a high level, and the restoration control signal CP_CT:r becomes a low level. Accordingly, the P type transistor P14 is set to a conductive state. As a result, a current is supplied to the balloon latch BL in parallel via both the diode DD2 and the P type transistor P14.

Furthermore, during the standby period STB_T, as illustrated in FIG. 7, the saving control signal CP_CT:s and the restoration control signal CP_CT:r become a high level. Accordingly, the P type transistor P14 is set to a non-conductive state. As a result, similarly to the function period FUC_T, a current is supplied to the balloon latch BL via both the diodes DD1 and DD2.

In the R-FF circuit according to the second embodiment, during the saving period STP_T and the restoration period RET_T, a current is supplied via a transistor instead of the diode DD3. Therefore, the current supply when changing the state of the R-FF circuit can be increased as compared with the first embodiment.

FIG. 9 illustrates an example in which the AND circuit ANC2 is provided in the R-FF circuit, but the present invention is not limited to this. That is, one common AND circuit ANC2 may be provided for a plurality of R-FF circuits.

In the embodiment, an example in which common saving control signals and restoration control signals are supplied to the plurality of R-FF circuits RFF has been described. Accordingly, in the embodiment, the power supply voltage can be supplied to a plurality of R-FF circuits from the signal lines configured to transmit common saving control signals and restoration control signals during the standby period. However, signal lines configured to transmit common saving control signals and restoration control signals may be divided into a plurality of groups of signal lines, and during the standby period, saving control signals and/or restoration control signals at a high level may be supplied only to signal lines connected to the R-FF circuits to which the power supply voltage is supplied, while saving control signals and restoration control signals at a low level may be supplied to the remaining signal lines. As a result, during the standby period, it is possible to reduce a standby current consumed by the R-FF circuits to which saving control signals and restoration control signals at a low level are supplied.

This makes it possible to achieve the reduction in standby current by, for example, defining saving control signals and restoration control signals to be supplied during the standby period for each unit repeater circuit. Alternatively, the reduction in standby current can be achieved also by providing a switch between the retention power supply terminal VDR_T of the R-FF circuit and, for example, the power supply line CVDR_L (FIG. 6) so as to separate the R-FF circuit, in which standby current is to be reduced, from the power supply line CVDR_L. However, in this case, for example, it is necessary to provide a switch, which leads to an increase in manufacturing cost.

In FIG. 3 and FIG. 9, an example in which the balloon latch BL is connected to the slave latch SAL via the transfer switch has been illustrated, but the present invention is not limited to this. For example, the balloon latch BL may be connected to the master latch MAL via the transfer switch, may be connected to both the master latch MAL and the slave latch SAL, or may be connected to a latch in which the master latch MAL and the slave latch SAL are combined.

In FIG. 1, an example in which a plurality of R-FF circuits RFF is formed in a common semiconductor well (for example, the N type semiconductor well N-well) has been illustrated, but the present invention is not limited to this. For example, the common semiconductor well may be divided into a plurality of semiconductor wells such that, for example, one R-FF circuit is formed in one semiconductor well. Even in this case, it is suitable to connect the retention power supply terminal VDR_T of each R-FF circuit to the signal line CST_L (FIG. 6) made up of a metal line. However, in this case, it is necessary to form isolation regions for separating the semiconductor wells on the semiconductor chip, which leads to an increase in manufacturing cost.

In the foregoing, the invention made by the inventors of this application has been specifically described based on the embodiments, but the present invention is not limited to the embodiments above, and it goes without saying that various modifications can be made within the range not departing from the gist of the invention.

What is claimed is:

1. A semiconductor device comprising:
a first power supply line configured to transmit a first power supply voltage;
a second power supply line to which the first power supply voltage is supplied via a switch circuit controlled by a first control signal from a power supply manager; and
a plurality of memory circuits each having a latch circuit and a flip-flop circuit and capable of saving data stored in the flip-flop circuit to the latch circuit by a second control signal from the power supply manager and retaining the saved data,
wherein the flip-flop circuit is connected to the second power supply line and operates using the first power supply voltage on the second power supply line as a power supply voltage, and
wherein the latch circuit is connected to a signal line configured to transmit the second control signal by a first unidirectional circuit, and the latch circuit operates using a second power supply voltage supplied via the first unidirectional circuit as a power supply voltage when it retains the data.

2. The semiconductor device according to claim 1,
wherein the power supply manager is connected to the first power supply line and operates using the first power supply voltage on the first power supply line as a power supply voltage, and
wherein the signal line is connected to the power supply manager,
the semiconductor device further comprising a repeater circuit connected between the signal line and the memory circuit and configured to supply the second control signal to the memory circuit.

3. The semiconductor device according to claim 2,
wherein the latch circuit includes a balloon latch circuit provided with a pair of first inverter circuits which are cross-connected to each other and operate using the second power supply voltage as an operating voltage,
wherein the flip-flop circuit is a master-slave flip-flop circuit,
wherein the memory circuit includes a saving transfer switch connected between the master-slave flip-flop circuit and the balloon latch circuit and controlled by the second control signal, and
wherein a voltage of the second control signal when the saving transfer switch is set to a non-conductive state is supplied to the balloon latch circuit as the second power supply voltage via the first unidirectional circuit.

4. The semiconductor device according to claim 3, further comprising a second unidirectional circuit connected between the second power supply line and the balloon latch circuit,
wherein a third power supply voltage is supplied to the balloon latch circuit via the second unidirectional circuit.

5. The semiconductor device according to claim 4, further comprising a first semiconductor well region of a first conductivity type formed in a substrate,
wherein a first transistor of a second conductivity type constituting the first inverter circuit in the memory circuit has a first semiconductor region of the second conductivity type formed in the first semiconductor well region,
wherein a second transistor of the second conductivity type constituting the master-slave flip-flop circuit in the memory circuit has a second semiconductor region of the second conductivity type formed in the first semiconductor well region,
wherein the first unidirectional circuit includes a first diode element having a third semiconductor region of the second conductivity type formed in the first semiconductor well region and connected to the signal line,
wherein the second unidirectional circuit includes a second diode element having a fourth semiconductor region of the second conductivity type formed in the first semiconductor well region and connected to the second power supply line, and
wherein the second power supply voltage or the third power supply voltage is supplied to the first transistor from the first semiconductor well region.

6. The semiconductor device according to claim 5,
wherein the memory circuit includes a restoration transfer switch connected between the master-slave flip-flop circuit and the balloon latch circuit and controlled by a third control signal from the power supply manager.

7. The semiconductor device according to claim 2,
wherein the repeater circuit includes a buffer circuit connected between the signal line and the latch circuit and operates using the second power supply voltage as a power supply voltage.
